(19) United States
(12) Patent Application Publication
(10) Pub. No.: US 2026/0231665 A1
(43) Pub. Date: Aug. 6, 2026

(54) DEVICE AND METHOD FOR MANUFACTURING DISPLAY PANEL, AND METHOD OF MANUFACTURING ELECTRONIC DEVICE INCLUDING THE DISPLAY PANEL

(71) Applicant: Samsung Display Co., LTD., Yongin-si (KR)

(72) Inventors: Myungkyu KIM, Yongin-si (KR); Hyeonsik KIM, Yongin-si (KR); Yong YEO, Yongin-si (KR); Yongsic JEON, Yongin-si (KR); Kyunghoon CHUNG, Yongin-si (KR)

(21) Appl. No.: 19/451,267

(22) Filed: Jan. 16, 2026

(30) Foreign Application Priority Data
Feb. 4, 2025 (KR) 10-2025-0013931

(51) Int. Cl. H10K 71/16; H10K 59/12; H10P 72/76

(52) U.S. Cl. CPC H10K 71/166; H10K 59/1201; H10P 72/7606

(57) ABSTRACT

A device for manufacturing a display panel from an object includes a chamber, a first support unit disposed within the chamber to support an edge area of an object to be processed, and a second support unit disposed on the first support unit to press the edge area of the object to be processed. The second support unit includes a contact member facing the first support unit and a magnetic member including a magnet.

This application claims priority to Korean Patent Application No. 10-2025-0013931, filed on February 4, 2025, and all the benefits accruing therefrom under 35 U.S.C. §119, the content of which in its entirety is herein incorporated by reference.

### BACKGROUND

### 1. Field

Embodiments relate to a device and a method for manufacturing a display panel. Embodiments relate to a method of manufacturing an electronic device including such a display panel.

### 2. Description of the Related Art

An electronic device may include a display panel as a display element for displaying an image or a video. An image or a video may be displayed on the display panel through a pixel included as a display element. A single pixel may include a plurality of sub-pixels. The sub-pixel may include a light-emitting element and a sub-pixel circuit electrically connected to the light-emitting element to drive the light-emitting element. The light-emitting element may include a light-emitting diode, such as an organic light-emitting diode. The sub-pixel circuit may include one or more thin-film transistors and various wiring.

### SUMMARY

A process of manufacturing a display panel may include a process of arranging a deposition material on an object to be processed (e.g., a substrate). The deposition material may be disposed (e.g., deposited) on the object to be processed in a predetermined pattern, and the deposition material disposed on the object to be processed may be also referred to as a deposition pattern. A deposition mask may be used to arrange the deposition pattern. After the deposition mask is brought into close contact with the object to be processed, a deposition material may be sprayed toward the deposition mask and the object to be processed. The deposition material may be disposed on the object to be processed by passing through an opening provided in a predetermined pattern in the deposition mask. The deposition material disposed on the object to be processed by passing through the opening defined in the deposition mask may have the predetermined pattern described above. A structure, such as a support unit, which holds the object to be processed may be used to bring the object to be processed into close contact with the deposition mask. The support unit of the object to be processed may hold an edge area of the object to be processed. A support unit capable of handling objects of various sizes to be processed, that is, a support unit capable of stably holding objects of various sizes to be processed, is desired.

Additional features will be set forth in part in the description which follows and, in part, will be apparent from the description, or may be learned by practice of the presented embodiments of the disclosure.

In an embodiment of the disclosure, a device for manufacturing a display panel includes a chamber, a first support unit disposed within the chamber to support an edge area of an object to be processed, and a second support unit disposed on the first support unit to press the edge area of the object to be processed, wherein the second support unit includes a contact member facing the first support unit and a magnetic member including a magnet.

In an embodiment, the magnetic member may be disposed on the contact member or embedded in the contact member.

In an embodiment, the first support unit may include a first support member which is in direct contact with the object to be processed and supports the object to be processed, and a hinge member connected to the first support member.

In an embodiment, the first support unit may further include a second support member which is rotatably connected to the hinge member and has a size different from a size of the first support member.

In an embodiment, the device may further include a cool plate disposed on the second support unit and a magnetic force unit disposed on the cool plate.

In an embodiment, the cool plate may include an embossing which protrudes in a direction toward the object to be processed.

In an embodiment, grooves may be respectively defined in the cool plate and the magnetic force unit in the edge area, and the grooves may overlap the second support unit.

In an embodiment, an area in which the first support unit supports the object to be processed and an area in which the second support unit presses the object to be processed may overlap each other.

In an embodiment, the second support unit may include a plurality of contact members and a plurality of magnetic members, and the plurality of contact members and the plurality of magnetic members may be arranged along an outline of the object to be processed.

In an embodiment, the device may further include a deposition source disposed within the chamber and facing the object to be processed, and a deposition mask disposed between the object to be processed and the deposition source.

In an embodiment of the disclosure, a method of manufacturing a display panel includes loading an object to be processed into a chamber, supporting an edge area of the object to be processed by a first support unit, pressing the edge area of the object to be processed by a second support unit, and arranging a deposition material on the object to be processed, wherein the second support unit includes a contact member facing the first support unit and in contact with the object to be processed, and a magnetic member including a magnet.

In an embodiment, the first support unit may include a first support member which is in direct contact with the object to be processed and supports the object to be processed, and a hinge member connected to the first support member.

In an embodiment, the first support unit may further include a second support member which is rotatably connected to the hinge member and has a size different from a size of the first support member.

In an embodiment, the method may further include bringing the object to be processed into contact with a deposition mask provided within the chamber.

In an embodiment, the method may further include bringing a cool plate into contact with the object to be processed, and bringing the object to be processed and the deposition mask into close contact with each other through a magnetic force unit.

In an embodiment, grooves may be respectively defined in the cool plate and the magnetic force unit in the edge area, and the grooves may overlap the second support unit.

In an embodiment, an area in which the first support unit supports the object to be processed, an area in which the second support unit presses the object to be processed, and the grooves in the cool plate and the magnetic force unit may overlap one another.

In an embodiment of the disclosure, a method of manufacturing an electronic device includes preparing a display panel, and coupling the display panel with a housing, wherein the preparing of the display panel includes loading an object to be processed into a chamber, supporting an edge area of the object to be processed by a first support unit, pressing the edge area of the object to be processed by a second support unit, and arranging a deposition material on the object to be processed, wherein the second support unit includes a contact member facing the first support unit and in contact with the object to be processed, and a magnetic member including a magnet.

In an embodiment, the first support unit may include a first support member which is in direct contact with the object to be processed and supports the object to be processed, and a hinge member connected to the first support member.

In an embodiment, the first support unit may include a second support member which is rotatably connected to the hinge member and has a size different from a size of the first support member.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a cross-sectional view of a device for manufacturing an embodiment of a display panel;

FIG. 2A is an enlarged cross-sectional view of an embodiment of a portion of the device for manufacturing a display panel;

FIG. 2B is an enlarged cross-sectional view of an embodiment of a portion of the device for manufacturing a display panel;

FIG. 3 is a schematic cross-sectional view of an embodiment of a second support unit;

FIG. 4A is a schematic side view of an embodiment of a first support unit;

FIG. 4B is a schematic plan view of an embodiment of the first support unit;

FIG. 5A is a schematic side view of an embodiment of the first support unit;

FIG. 5B is a schematic plan view of an embodiment of the first support unit;

FIG. 6A is a schematic side view of an embodiment of the first support unit;

FIG. 6B is a schematic plan view of an embodiment of the first support unit;

FIG. 7 is an enlarged plan view illustrating an embodiment of a portion of a device for manufacturing a display panel;

FIG. 8 is an enlarged plan view illustrating an embodiment of a portion of a device for manufacturing a display panel;

FIGS. 9A, 9B, 9C, 9D, 9E, 9F, and 9G are cross-sectional views schematically illustrating an embodiment of processes of a method of manufacturing a display panel;

FIG. 10 is a block diagram of an embodiment of an electronic device;

FIGS. 11, 12, and 13 are schematic diagrams of embodiments of an electronic device;

FIG. 14 is a schematic plan view of an embodiment of an electronic device; and

FIG. 15 is a cross-sectional view of an embodiment of a display panel.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" includes any and all combinations of one or more of the associated listed items. Throughout the disclosure, the expression "at least one of a, b, or c" indicates only a, only b, only c, both a and b, both a and c, both b and c, all of a, b, and c, or variations thereof.

As the disclosure allows for various changes and numerous embodiments, illustrative embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Embodiments will be described below in more detail with reference to the accompanying drawings. Those components that are the same or are in correspondence are rendered the same reference numeral regardless of the figure number, and redundant descriptions thereof are omitted.

Terms, such as "first" and "second," are used herein merely to describe a variety of elements, but the elements are not limited by the terms. Such terms are used only for the purpose of distinguishing one element from another element.

Herein, an expression used in the singular encompasses the expression of the plural, unless it has a clearly different meaning in the context.

Herein, it will be further understood that the terms "comprises" and/or "comprising" used herein specify the presence of stated features or components, but do not preclude the presence or addition of one or more other features or components.

When a layer, region, or element is herein referred to as being "formed on" another layer, area, or element, it may be directly or indirectly formed on the other layer, region, or element. That is, for example, one or more intervening layers, regions, or elements may be therebetween.

When a layer, region, or component is herein referred to as being "connected" to another layer, region, or component, it may be "directly connected" to the other layer, region, or component or/and may be "indirectly connected" to the other layer, region, or component with other layer, region, or component disposed therebetween. For example, when a layer, region, or component is herein referred to as being "electrically connected" to another layer, region, or component, it may be "directly electrically connected" to the other layer, region, or component and/or may be "indirectly electrically connected" to other layer, region, or component with other layer, region, or component disposed therebetween.

"A and/or B" as used herein may include "A," "B," or "A and B." In addition, "at least one of A and B" may include "A," "B," or "A and B."

Herein, the expression "in a plan view" means when the target portion is viewed from above (e.g., when viewed in a direction perpendicular to the upper surface of the substrate), and the expression "in a cross-sectional view" means when a cross-section obtained by vertically cutting the target portion is viewed from the side.

Herein, when a first component is described to "overlap" a second component, it means that the first component is disposed above or below the second component so that at least a portion of the first component overlaps the second component in a plan view.

Herein, when an illustrative embodiment may be implemented differently, a predetermined process order may be performed differently from the described order. For example, two consecutively described processes may be performed substantially at the same time or performed in an order opposite to the described order.

In the drawings, sizes of components in the drawings may be exaggerated or contracted for convenience of explanation. In other words, since sizes and thicknesses of components in the drawings are arbitrarily illustrated for convenience of explanation, the following disclosure is not limited thereto.

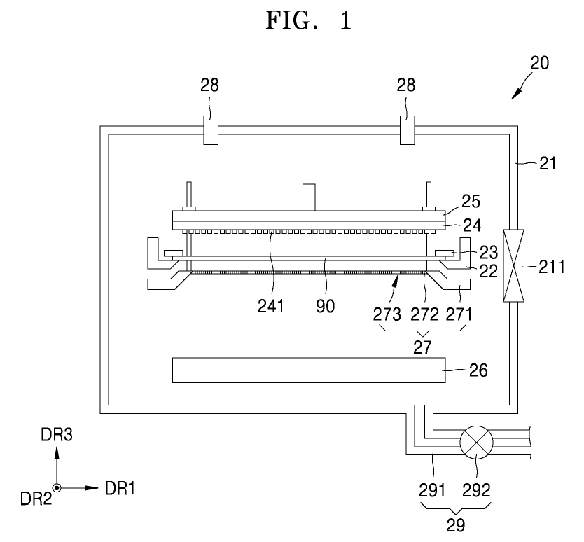

FIG. 1 is a cross-sectional view of an embodiment of a device for manufacturing a display panel.

Referring to FIG. 1, a device 20 for manufacturing a display panel may include a chamber 21, a first support unit 22, a second support unit 23, a cool plate 24, a magnetic force unit 25, a deposition source 26, a deposition mask 27, a vision unit 28, and a pressure control unit 29. FIG. 1 shows an embodiment in which an object 90, which is to be processed, is clamped between the first support unit 22 and the second support unit 23, and the cool plate 24, the magnetic force unit 25, and the deposition mask 27 are spaced apart from the object 90, which is to be processed.

Herein, the object 90, which is to be processed, may refer to a semi-finished product of a display panel as a target to be processed by the device 20 for manufacturing a display panel. In an embodiment, the device 20 for manufacturing a display panel may be a deposition device which arranges a deposition material on the object 90, which is to be processed. In other words, a process intended for the device 20 for manufacturing a display panel may be a deposition process. In an embodiment, the process (e.g., a deposition process) intended for the device 20 for manufacturing a display panel may be part of a process of manufacturing a display panel. In other words, after the process (e.g., a deposition process) intended for the device 20 for manufacturing a display panel is performed, the object 90, which is to be processed, may be transported for subsequent processing.

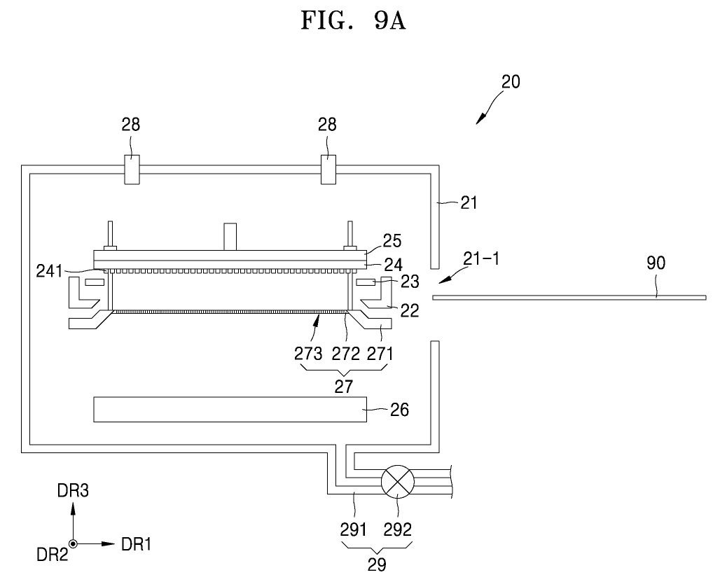

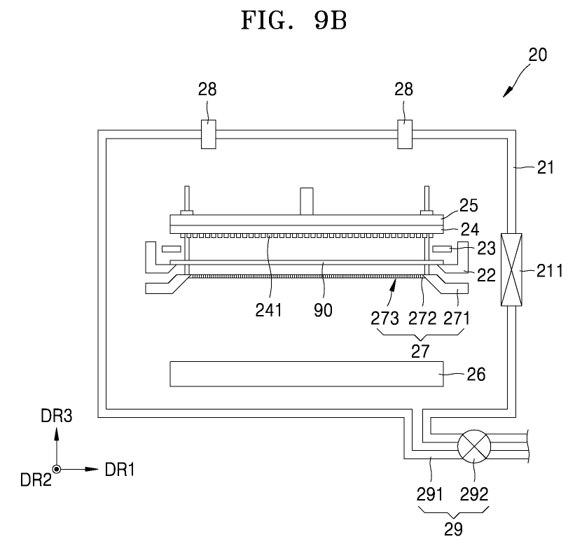

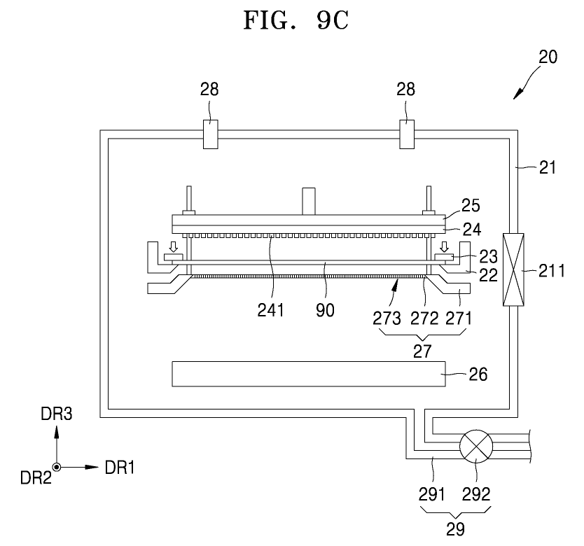

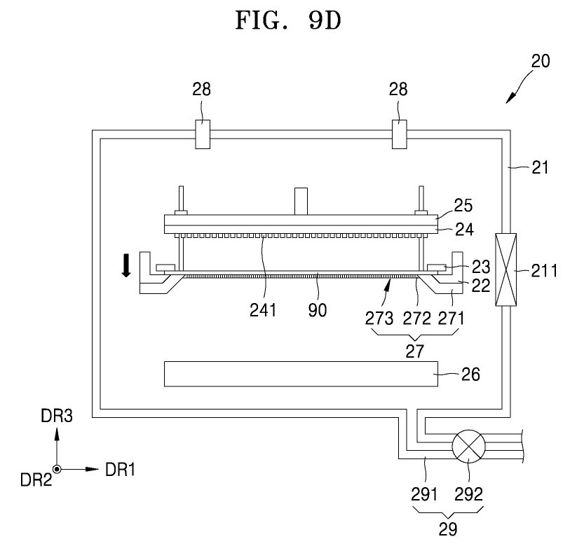

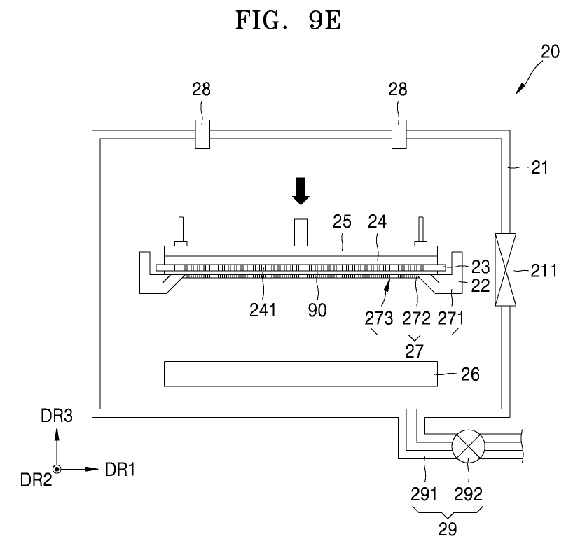

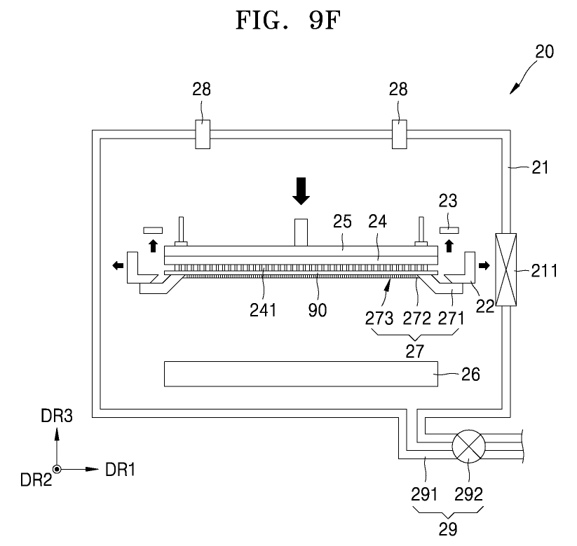

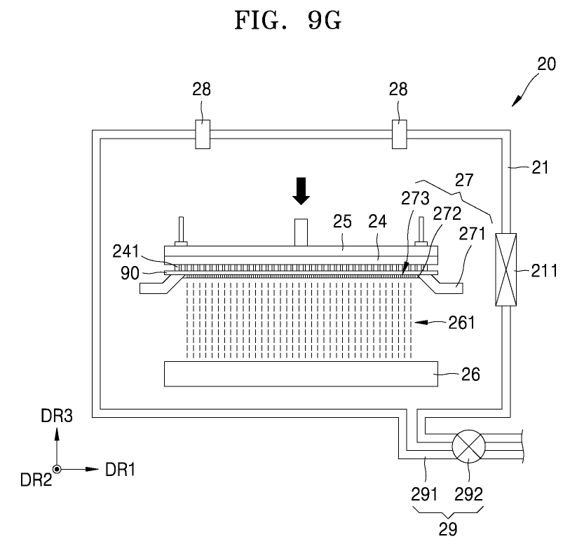

The chamber 21 may have a space defined inside, and a portion of the chamber 21 may be opened. A gate valve 211 may be installed in an opening area 21-1 (refer to FIG. 9A) of the chamber 21. Depending on an operation of the gate valve 211, the opening area 21-1 of the chamber 21 may be opened or closed.

The first support unit 22 may be provided to support an edge area of the object 90, which is to be processed. In an embodiment, the first support unit 22 may be provided in the form of a frame which supports the edge area of the object 90, which is to be processed. In an embodiment, the first support unit 22 may be provided in the form of a plurality of support pieces which partially support the edge area of the object 90, which is to be processed. In an embodiment, the first support unit 22 may be disposed within the chamber 21 to enable translational movement in a single direction (e.g., a third direction DR3). In an embodiment, the first support unit 22 may be coupled with the object 90, which is to be processed, from the outside of the chamber 21 and then loaded into the chamber 21. Herein, a case is mainly described in which the first support unit 22 is disposed in the chamber 21 and the object 90, which is to be processed, is loaded into the chamber 21 from the outside of the chamber 21.

The first support unit 22 may move relative to the cool plate 24, the magnetic force unit 25, and/or the deposition mask 27. In an embodiment, while the first support unit 22 is fixed, the cool plate 24, the magnetic force unit 25, and/or the deposition mask 27 may be moved. In an embodiment, while the cool plate 24, the magnetic force unit 25, and/or the deposition mask 27 may be fixed, the first support unit 22 may be moved. In an embodiment, the first support unit 22 may be movable in the third direction DR3, for example. In an embodiment, the first support unit 22 may be movable in a first direction DR1, for example. Although not shown, the first support unit 22 may include any suitable means for performing the movements described above.

The second support unit 23 may be disposed on the first support unit 22. The object 90, which is to be processed, may be disposed between the first support unit 22 and the second support unit 23. The second support unit 23 may be provided to press the edge area of the object 90, which is to be processed. In an embodiment, the second support unit 23 may be provided in the form of a frame which presses the edge area of the object 90, which is to be processed. In an embodiment, the second support unit 23 may be provided in the form of a plurality of support pieces which partially press the edge area of the object 90, which is to be processed. In an embodiment, the second support unit 23 may be disposed within the chamber 21 to enable translational movement in a single direction (e.g., in the third direction DR3). In an embodiment, the second support unit 23 may be coupled with the object 90, which is to be processed, from the outside of the chamber 21 and then loaded into the chamber 21. Herein, a case is mainly described in which the second support unit 23 is disposed in the chamber 21 and the object 90, which is to be processed, is loaded into the chamber 21 from the outside of the chamber 21.

The second support unit 23 may move relative to the first support unit 22. In an embodiment, the second support unit 23 may be moved while the first support unit 22 is fixed. In an embodiment, the first support unit 22 may be moved while the second support unit 23 is fixed. In an embodiment, the second support unit 23 may be movable in the third direction DR3, for example. Although not shown, the second support unit 23 may include any suitable means for performing the movements described above.

In an embodiment, when the object 90, which is to be processed, is disposed on the first support unit 22, the second support unit 23 may be moved and may press the object 90, which is to be processed, so that the object 90, which is to be processed, may be clamped between the first support unit 22 and the second support unit 23. In other words, by the operation of the first support unit 22 supporting the object 90, which is to be processed, and the operation of the second support unit 23 pressing the object 90, which is to be processed, the object 90, which is to be processed, may be fixed between the first support unit 22 and the second support unit 23. In an embodiment, the first support unit 22, the second support unit 23, and the object 90, which is to be processed, clamped between the first support unit 22 and the second support unit 23 may be moved as a single unit.

The cool plate 24 may be disposed within the chamber 21 and may be directed toward the object 90, which is to be processed. The cool plate 24 may overlap the entirety of the object 90, which is to be processed, including a central area and edge area of the object 90, which is to be processed. In an embodiment, the cool plate 24 may be disposed on the object 90, which is to be processed, in the third direction DR3, for example. The cool plate 24 may include a plurality of embossings 241 protruding toward the object 90, which is to be processed. The cool plate 24 may contact the object 90, which is to be processed, thereby maintaining the object 90, which is to be processed, flat during the deposition process. In addition, the cool plate 24 may press and fix the object 90, which is to be processed, through the plurality of embossings 241 protruding toward the object 90, which is to be processed, thereby preventing misalignment of the object 90, which is to be processed, and the deposition mask 27 due to unwanted movement of the object 90, which is to be processed, during the deposition process. In an embodiment, the cool plate 24 may be movable in a single direction, e.g., in the third direction DR3. In an embodiment, the cool plate 24 may be disposed on the first support unit 22 and the second support unit 23.

The magnetic force unit 25 may be disposed within the chamber 21 and may be directed toward the object 90, which is to be processed. In an embodiment, the magnetic force unit 25 may be disposed on the cool plate 24 in the third direction DR3, for example. The magnetic force unit 25 may overlap the entirety of the object 90, which is to be processed, including the central area and edge area of the object 90, which is to be processed. In an embodiment, the magnetic force unit 25 may cover an entirety of the cool plate 24. In an embodiment, the magnetic force unit 25 may be disposed on the cool plate 24 in the third direction DR3, for example. The magnetic force unit 25 may include one or more magnets arranged in a single direction (e.g., in the first direction DR1 or a second direction DR2). The magnetic force unit 25 may apply magnetic force to the deposition mask 27 so that the deposition mask 27 may come into close contact with the object 90, which is to be processed. In addition, the magnetic force unit 25 may apply magnetic force to the deposition mask 27 and fix the deposition mask 27, thereby preventing unwanted movement of the deposition mask 27 during the deposition process. In an embodiment, the magnetic force unit 25 may be movable in a single direction, e.g., in the third direction DR3. The magnetic force unit 25 and the cool plate 24 may move as a single unit or individually.

The deposition source 26 may be disposed in the chamber 21 to face the object 90, which is to be processed. In an embodiment, the deposition source 26 may be disposed to be directed toward the object 90, which is to be processed, and the deposition mask 27. A deposition material may be stored in the deposition source 26. The deposition source 26 may apply heat to the deposition material to vaporize or sublimate the deposition material. The deposition source 26 may include a heat source for performing this process. The deposition source 26 may be disposed to be fixed within the chamber 21 or may be disposed within the chamber 21 to be linearly moved in a single direction. For convenience of explanation, a case is described below in which the deposition source 26 is disposed to be fixed within the chamber 21.

The deposition mask 27 may be disposed to be opposite to the cool plate 24 with the object 90, which is to be processed, therebetween. In other words, the object 90, which is to be processed, may be disposed between the deposition mask 27 and the cool plate 24. In an embodiment, the deposition mask 27 may be disposed between the object 90, which is to be processed, and the deposition source 26. In an embodiment, the first support unit 22, the second support unit 23, and the object 90, which is to be processed, may be disposed in the third direction DR3 of the deposition mask 27. In an embodiment, the deposition mask 27 may move relative to the first support unit 22, the second support unit 23, and the object 90, which is to be processed. In an embodiment, while the deposition mask 27 is fixed, the first support unit 22, the second support unit 23, and the object 90, which is to be processed, may be moved in a single direction, e.g., the third direction DR3. In an embodiment, while the first support unit 22, the second support unit 23, and the object 90, which is to be processed, are fixed, the deposition mask 27 may be moved in a single direction, e.g., the third direction DR3.

The deposition mask 27 may include a mask frame 271 and a mask sheet 272. The mask frame 271 may overlap the first support unit 22 and the second support unit 23. The mask frame 271 may overlap the edge area of the object 90, which is to be processed. In an embodiment, the mask frame 271 may be provided in the form of a frame which overlaps the edge area of the object 90, which is to be processed. The mask sheet 272 may be fixed to the mask frame 271. The mask sheet 272 may overlap the central area of the object 90, which is to be processed. The mask sheet 272 may define a plurality of holes 273. The plurality of holes 273 in the mask sheet 272 may define patterns along which a deposition material (e.g., sprayed from the deposition source 26) is to be disposed on the object 90, which is to be processed. Therefore, the plurality of holes 273 in the mask sheet 272 may be defined in the mask sheet 272 in a predetermined shape and arrangement. When the object 90, which is to be processed, and the deposition mask 27 are in close contact with each other, it may be understood that the object 90, which is to be processed, and the mask sheet 272 are actually in close contact with each other. To enable the object 90, which is to be processed, and the mask sheet 272 to be brought into close contact with each other, the mask frame 271 may be provided in a shape capable of accommodating at least a portion of the first support unit 22.

The vision unit 28 may be installed in the chamber 21 and may photograph positions of the object 90, which is to be processed, and deposition mask 27. In this case, the vision unit 28 may include a camera which photographs the object 90, which is to be processed, and the deposition mask 27. Based on an image captured by the vision unit 28, the positions of the object 90, which is to be processed, and deposition mask 27 may be identified. Based on this image, the position of the object 90, which is to be processed, may be fine-tuned or the position of the deposition mask 27 may be fine-tuned.

The pressure control unit 29 may be connected to chamber 21 and may regulate pressure within the chamber 21. In an embodiment, the pressure control unit 29 may regulate the pressure within the chamber 21 to be equal to or similar to atmospheric pressure. In addition, the pressure control unit 29 may regulate the pressure within the chamber 21 to be equal to or similar to a vacuum state. The pressure control unit 29 may include a connection pipe 291 connected to the chamber 21 and a pump 292 installed in the connection pipe 291. Depending on an operation of the pump 292, outside air may be introduced through the connection pipe 291, or gas within the chamber 21 may be discharged to the outside through the connection pipe 291.

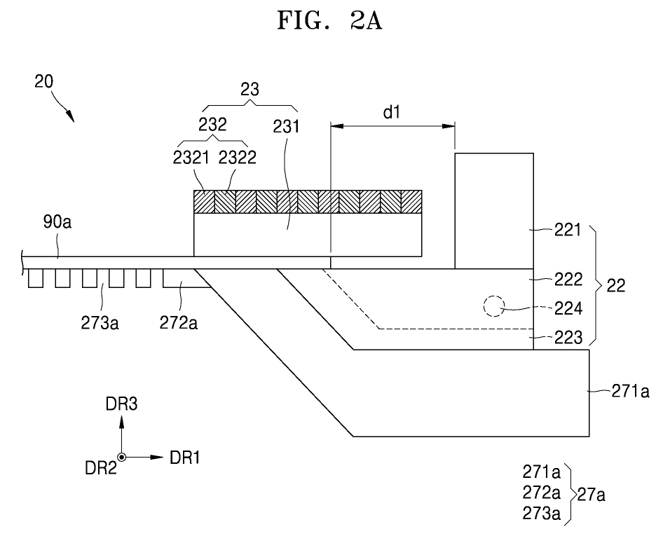

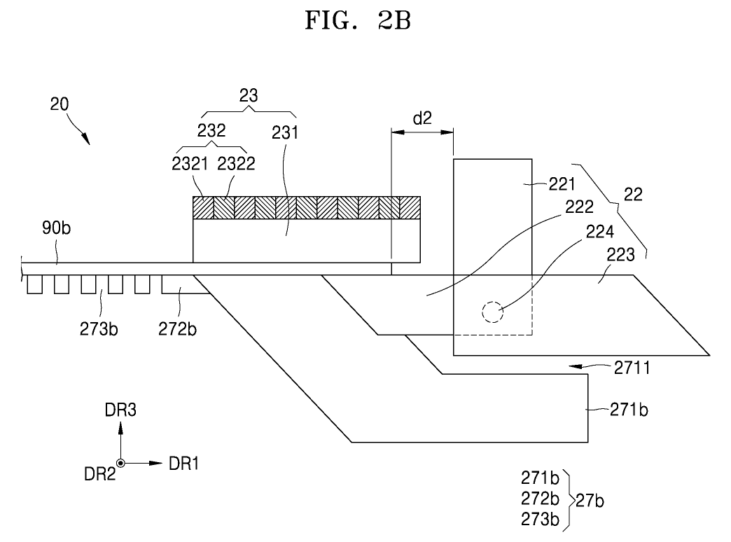

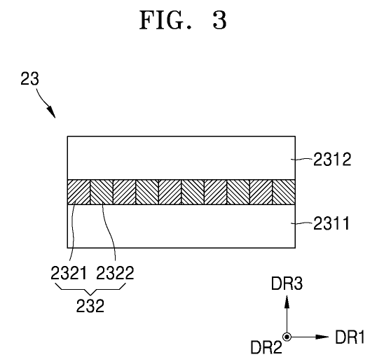

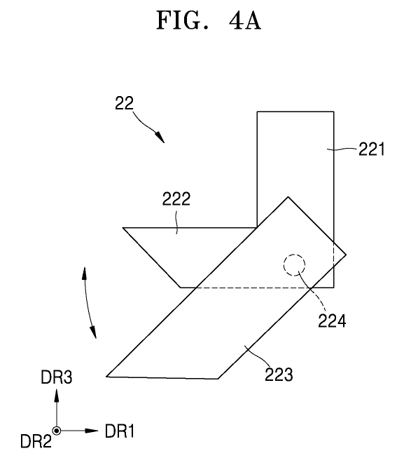

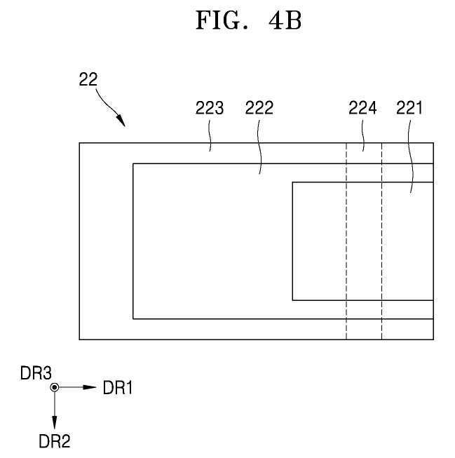

FIG. 2A is an enlarged cross-sectional view of an embodiment of a portion of the device 20 for manufacturing a display panel. FIG. 2B is an enlarged cross-sectional view of an embodiment of a portion of the device 20 for manufacturing a display panel. FIG. 3 is a schematic cross-sectional view of an embodiment of the second support unit 23. FIG. 4A is a schematic side view of an embodiment of the first support unit 22. FIG. 4B is a schematic plan view of an embodiment of the first support unit 22.

Referring to FIGS. 2A and 2B, each embodiment may include different objects to be processed and deposition masks. In an embodiment, FIG. 2A shows a first object 90a, which is to be processed, and a first deposition mask 27a, and FIG. 2B shows a second object 90b, which is to be processed, and a second deposition mask 27b, for example. The first object 90a, which is to be processed, and the second object 90b, which is to be processed, may have different sizes and/or shapes. The first deposition mask 27a and second deposition mask 27b may have different sizes and/or shapes. The embodiments of FIGS. 2A and 2B may include the same first support unit 22 and second support unit 23.

The first support unit 22 and the second support unit 23 of the device 20 for manufacturing a display panel of embodiments may correspond to objects to be processed (e.g., the first object 90a, which is to be processed, and the second object 90b, which is to be processed) having various shapes and/or sizes. In other words, the device 20 for manufacturing a display panel of embodiments may correspond to objects to be processed, of various shapes and/or sizes (e.g., the first object 90a, which is to be processed, and the second object 90b, which is to be processed) without the need to replace the first support unit 22 or the second support unit 23. The characteristic structure of embodiments which provides these effects is described in detail below.

Referring to FIGS. 2A and 2B together with FIGS. 4A and 4B, the first support unit 22 may include a main body 221, a first support member 222, a second support member 223, and a hinge member 224. FIGS. 2A and 2B show an embodiment of the device 20 for manufacturing a display panel, to which the embodiment of the first support unit 22 shown in FIGS. 4A and 4B is described.

The main body 221 of the first support unit 22 may extend in a single direction, e.g., in the third direction DR3. Any means (e.g., an actuator or the like) for moving the first support unit 22 may be connected to the main body 221. When the main body 221 moves, the first support member 222, the second support member 223, and the hinge member 224 may move together with the main body 221.

The first support member 222 may be connected to the main body 221. In an embodiment, the first support member 222 may be integrally provided as a single body with the main body 221. The first support member 222 may be in a form which protrudes from the main body 221 in a single direction (e.g., in the opposite direction of the first direction DR1). In an alternative embodiment, the main body 221 of the first support unit 22 may extend in one direction (e.g., in the third direction DR3) and bend in another direction (e.g., in the opposite direction of the first direction DR1), and the bent portion may be understood as the first support member 222.

The hinge member 224 may be connected to the first support member 222. In an embodiment, the hinge member 224 may be provided in the form of a rod extending in a single direction, e.g., in the second direction DR2. In an embodiment, the first support member 222 may define an opening area extending in the second direction DR2, for example, and the hinge member 224 may be provided in the form of a rod disposed in the opening area. The hinge member 224 may provide a hinge structure to the first support unit 22.

The second support member 223 may be connected to the hinge member 224. In an embodiment, the second support member 223 may be rotatably connected to the hinge member 224. In an embodiment, the first support member 222 and the second support member 223 may define opening areas extending therethrough, respectively, and the hinge member 224 may be disposed to simultaneously pass through the opening areas in the first support member 222 and second support member 223 and may connect the first support member 222 and the second support member 223 to each other. In other words, the first support member 222 and the second support member 223 may be connected to each other as a hinge structure having the hinge member 224 as a common rotation axis. In other words, the first support member 222 and the second support member 223 may be coaxially connected through the hinge member 224. In an embodiment, the first support member 222 may be fixed to the main body 221 by being integrally provided as a single body with the main body 221, and the second support member 223 may rotate about the first support member 222.

In an embodiment, the hinge member 224 may be fixed to the first support member 222 (e.g., by being unitary with or bonded to the first support member 222), and the second support member 223 may rotate about the hinge member 224.

In an embodiment, the hinge member 224 may be fixed to the second support member 223 (e.g., by being unitary with or bonded to the second support member 223), and the second support member 223 and the hinge member 224 may together rotate with respect to the first support member 222.

FIG. 2A shows an embodiment in which the second support member 223 overlaps the first support member 222, and FIG. 2B shows an embodiment in which the second support member 223 is rotated about 180 degrees from the state shown in FIG. 2A.

The second support member 223 may have a size different from a size of the first support member 222. In an embodiment, the second support member 223 may be larger than the first support member 222. In an embodiment, when the first support member 222 and the second support member 223 overlap each other, the first support member 222 may be accommodated within the second support member 223. In an embodiment, the second support member 223 may have a space (e.g., a recess) for accommodating the first support member 222. FIG. 2A shows an embodiment in which the first support member 222 is stored within the second support member 223, and FIG. 2B shows an embodiment in which the first support member 222 is exposed.

As shown in FIG. 2A, the state in which the first support member 222 and the second support member 223 overlap each other, and the first support member 222 is accommodated within the second support member 223 is also referred to as a first state. As shown in FIG. 2B, the state in which the second support member 223 is rotated and the first support member 222 is exposed is also referred to as a second state. An object to be processed by the device 20 for manufacturing a display panel in the first state may be the first object 90a, which is to be processed, and an object to be processed by the device 20 for manufacturing a display panel in the second state may be the second object 90b, which is to be processed.

Referring to FIG. 2A, in the first state, the first object 90a, which is to be processed, may be disposed (e.g., mounted) on the second support member 223. In an embodiment, the second support member 223 may support an edge area of the first object 90a, which is to be processed, for example. The second object 90b, which is to be processed, may be disposed (e.g., mounted) on the first support member 222. In an embodiment, the first support member 222 may support the edge area of the first object 90a, which is to be processed, for example. However, in the illustrated embodiment, a portion of the first support member 222 may support a portion of the first object 90a, which is to be processed.

In an embodiment, the first object 90a, which is to be processed, may be smaller than the second object 90b, which is to be processed. In an embodiment, a first distance d1 between an edge of the first object 90a, which is to be processed, and the main body 221 of the first support unit 22 may be greater than a second distance d2 between an edge of the second object 90b, which is to be processed, and the main body 221 of the first support unit 22, for example. To stably support the smaller first object 90a, which is to be processed, the second support member 223 larger than the first support member 222 may be used. In an embodiment, by positioning the second support member 223 as in the first state shown in FIG. 2A, the first object 90a, which is to be processed, may be stably supported, for example. In this case, the first deposition mask 27a corresponding to the first object 90a, which is to be processed, may be used. The first deposition mask 27a may have a first mask frame 271a and a first mask sheet 272a, and define first holes 273a.

Referring to FIG. 2B, when the second deposition mask 27b is used to process the second object 90b, which is to be processed, and the second support member 223 is disposed as in the first state, a collision may occur between the second support member 223 and the second deposition mask 27b. To avoid this collision, the second support member 223 may be rotated to the second state by the hinge member 224. In the second state, the second object 90b, which is to be processed, may be supported by the first support member 222, and the second support member 223 may be oriented so as not to collide with the second deposition mask 27b. The second deposition mask 27b may have a second mask frame 271b and a second mask sheet 272b, and define second holes 273b. The first holes 273a and second holes 273b may have different sizes, shapes, patterns and/or arrangements. In an embodiment, the second deposition mask 27b may be rotated to define an additional space 2711 in which a portion of the second support member 223 disposed in the second state may be accommodated.

In summary, the first support unit 22 may have support members of various sizes to handle objects of various sizes to be processed, and may provide a structure in which a support member of a desired size may be selected and used through a hinge structure from among these support members. With this structure provided, it may not be desired to replace the first support unit 22 in response to a size of each object to be processed, and the efficiency of the device 20 for manufacturing a display panel may be increased.

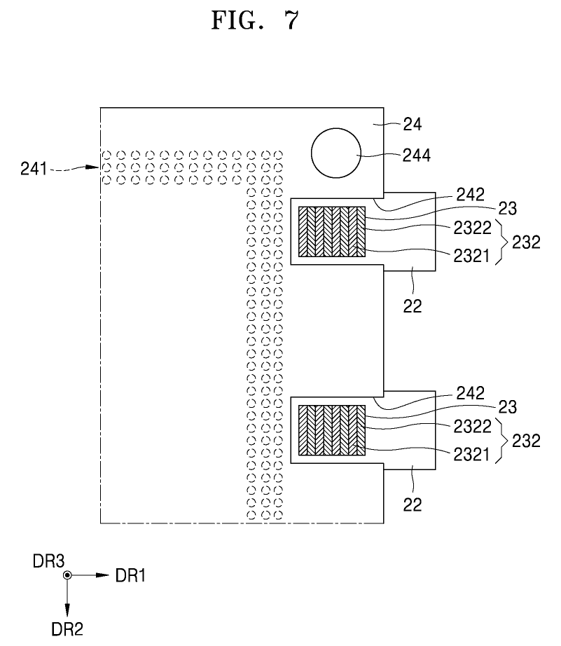

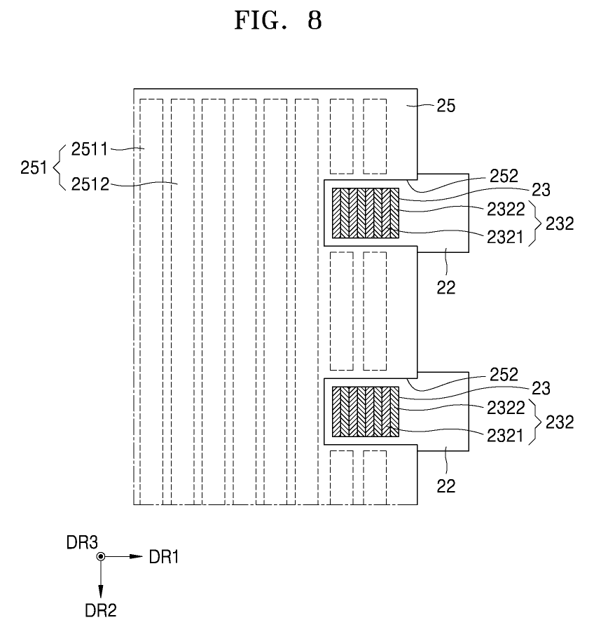

The second support unit 23 may be provided in a single size which may correspond to both the first object 90a, which is to be processed, of FIG. 2A and the second object 90b, which is to be processed, of FIG. 2B. As described below, the cool plate 24 or the magnetic force unit 25 may not be disposed in an area where the second support unit 23 is disposed (refer to FIGS. 7 and 8). Therefore, in the area where the second support unit 23 is disposed, magnetic force by the magnetic force unit 25 may not be applied to the deposition mask 27. When the size of the second support unit 23 is set too large, an area of the deposition mask 27 to which the magnetic force is not applied by the magnetic force unit 25 may increase, which may weaken the adhesion between the object 90, which is to be processed, and the deposition mask 27.

To solve this drawback, the second support unit 23 may include a contact member 231 and a magnetic member 232. The contact member 231 may face the first support unit 22. The contact member 231 may directly contact the first object 90a, which is to be processed, or the second object 90b, which is to be processed. In an embodiment, the contact member 231 may be a portion which clamps the first object 90a, which is to be processed, or the second object 90b, which is to be processed, together with the first support unit 22. In an embodiment, as shown in FIG. 2A, the first object 90a, which is to be processed, may be clamped between the contact member 231 of the second support unit 23 and the second support member 223 of the first support unit 22. In an embodiment, as shown in FIG. 2B, the second object 90b, which is to be processed, may be clamped between the contact member 231 of the second support unit 23 and the first support member 222 of the first support unit 22.

In an embodiment, the magnetic member 232 may be disposed on the contact member 231 and may include a magnet. In an embodiment, the magnetic member 232 may include a plurality of first magnets 2321 and a plurality of second magnets 2322. In an embodiment, the plurality of first magnets 2321 and the plurality of second magnets 2322 may be alternately arranged in a single direction, e.g., in the first direction DR1, for example. In an embodiment, the plurality of first magnets 2321 and the plurality of second magnets 2322 may extend in a direction (e.g., the second direction DR2) crossing the direction in which the plurality of first magnets 2321 and the plurality of second magnets 2322 are arranged (e.g., the first direction DR1). In an embodiment, the plurality of first magnets 2321 and the plurality of second magnets 2322 may be arranged such that directions of the poles of each magnet are opposite to each other. In an embodiment, the N poles of the plurality of first magnets 2321 may be directed toward the second direction DR2, and the N poles of a plurality of second magnets 2322 may be directed toward the opposite direction of the second direction DR2, for example. In other words, the N poles of the plurality of first magnets 2321 may be directed toward the opposite direction of the second direction DR2, and the N poles of a plurality of second magnets 2322 may be directed toward the second direction DR2.

Because the second support unit 23 includes the magnetic member 232, an additional magnetic force other than the magnetic force by the magnetic force unit 25 (refer to FIG. 1) may be applied to the first deposition mask 27a or the second deposition mask 27b, and thus, the adhesion between the object to be processed (e.g., the first object 90a, which is to be processed, or the second object 90b, which is to be processed) and a deposition mask (e.g., the first deposition mask 27a or the second deposition mask 27b) may become more solid. In addition, the second support unit 23 may be used regardless of the size of the object to be processed. In an embodiment, the second support unit 23 may be used for the first object 90a, which is to be processed, and also for the second object 90b, which is to be processed, for example. This is because, since the second support unit 23 includes the magnetic member 232, even when the magnetic force by the magnetic force unit 25 is not applied to the deposition mask (e.g., the first deposition mask 27a or the second deposition mask 27b) in the area where the second support unit 23 is disposed, the second support unit 23 may apply magnetic force instead. In other words, it is not desired to consider the loss of magnetic force due to the size of the second support unit 23. Thus, with this structure provided, it may not be desired to replace the second support unit 23 in response to a size of each object to be processed, and the efficiency of the device 20 for manufacturing a display panel may be increased.

FIGS. 2A and 2B show an embodiment in which the magnetic member 232 is disposed on the contact member 231, but the disclosure is not necessarily limited thereto. In another embodiment, referring to FIG. 3, the second support unit 23 may include a first contact member 2311 and a second contact member 2312, and the magnetic member 232 may be sandwiched between the first contact member 2311 and the second contact member 2312. In other words, the magnetic member 232 may be embedded between the first contact member 2311 and the second contact member 2312.

FIGS. 4A and 4B show two sizes of support members, e.g., the first support member 222 and the second support member 223, but the disclosure is not necessarily limited to these numbers.

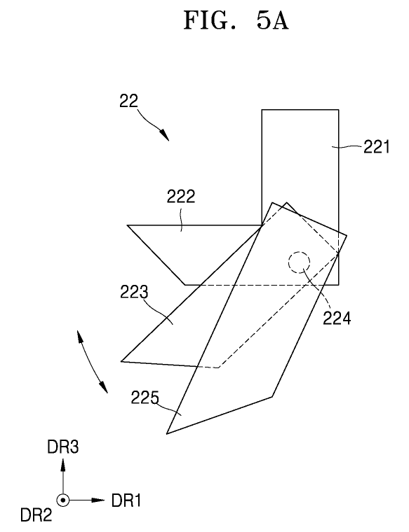

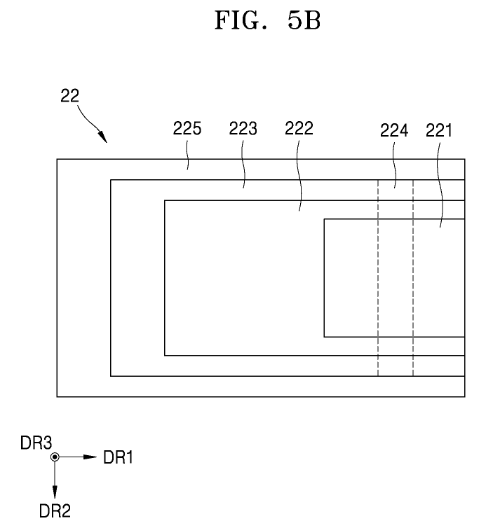

FIG. 5A is a schematic side view of an embodiment of the first support unit 22. FIG. 5B is a schematic plan view of an embodiment of the first support unit 22.

Referring to FIGS. 5A and 5B, the first support unit 22 may include the first support member 222, the second support member 223, and a third support member 225. The first support member 222, the second support member 223, and the third support member 225 may be coaxially connected through the hinge member 224. In an embodiment, the first support member 222 may be fixed integrally with the main body 221, and the second support member 223 and the third support member 225 may rotate about the first support member 222. In an embodiment, the second support member 223 and the third support member 225 may rotate about a rotation axis extending in the second direction DR2.

In an embodiment, the first support member 222 may be accommodated within the second support member 223, and the second support member 223 may be accommodated within the third support member 225. Depending on the size of the object to be processed, a support member of a suitable size may be selected and used. In an embodiment, in the case of an object to be processed having a relatively large size, the second support member 223 and the third support member 225 may be rotated similarly to the second state shown in FIG. 2B, for example, so that the object to be processed may be supported by the first support member 222. In the case of an object to be processed having a relatively small size, the first to third support members 222, 223, and 225 may be arranged similarly to the first state shown in FIG. 2A, so that the object to be processed may be supported by the second support member 223 or the third support member 225.

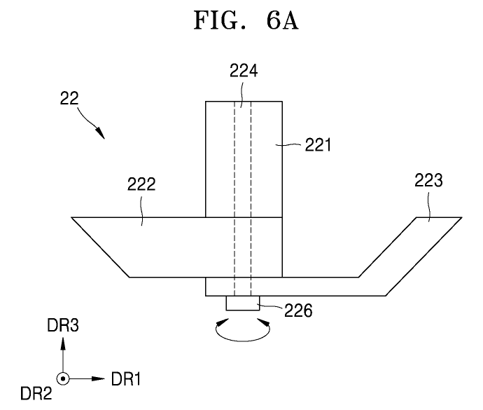

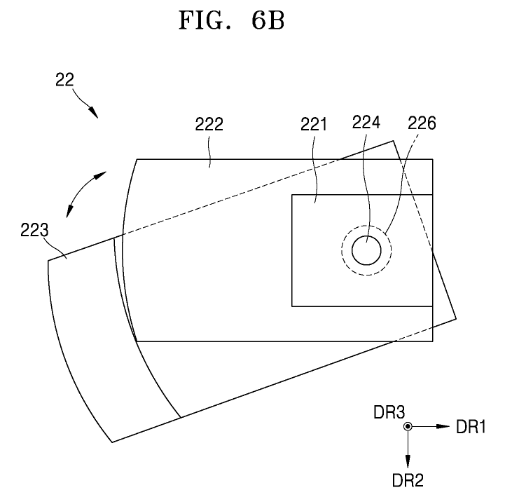

FIG. 6A is a schematic side view of an embodiment of the first support unit 22. FIG. 6B is a schematic plan view of an embodiment of the first support unit 22.

Referring to FIGS. 6A and 6B, the hinge member 224 may extend in the third direction DR3. In an embodiment, the main body 221 and the first support member 222 may define an opening area penetrating through the main body 221 and the first support member 222 in the third direction DR3, and the hinge member 224 may be disposed within the opening area. Accordingly, the second support member 223 may rotate about a rotation axis extending in the third direction DR3. An anti-detachment member 226 may be provided at one end of the hinge member 224. The anti-detachment member 226 may prevent the second support member 223 from detaching from the first support unit 22 by gravity, for example, in the opposite direction of the third direction DR3.

In an embodiment, the hinge member 224 may be fixed to the first support member 222 (e.g., by being unitary with or bonded to the first support member 222), and the second support member 223 may rotate about the hinge member 224. In this case, the anti-detachment member 226 may be provided at the opposite end in the third direction DR3 of the hinge member 224 to prevent the second support member 223 from detaching from the hinge member 224. FIG. 6A shows an embodiment of the above.

In an embodiment, the hinge member 224 may be fixed to the second support member 223 (e.g., by being unitary with or bonded to the second support member 223), and the second support member 223 and the hinge member 224 may together rotate with respect to the first support member 222. In this case, the anti-detachment member 226 may be provided at an end in the third direction DR3 of the hinge member 224 to prevent the hinge member 224 and the second support member 223 from detaching from the first support member 222.

One or more the disclosure is not limited to the number or size of support members as shown in FIGS. 4A to 6B. Any support unit that has a structure in which a support member of a size which may handle an object to be processed may be selected through a hinge structure, the support unit may be considered to fall within the scope of embodiments regardless of the number, size, or shape of the support member.

FIG. 7 is an enlarged plan view illustrating an embodiment of a portion of a device for manufacturing a display panel.

FIG. 7 shows the first support unit 22, the second support unit 23, and the cool plate 24. The magnetic force unit 25 (refer to FIG. 1) is omitted for convenience of illustration.

Referring to FIGS. 1 and 7, the first support unit 22 and the second support unit 23 may overlap each other in a plan view. In an embodiment, the first support unit 22 and the second support unit 23 may overlap each other when viewed from the second direction DR2, for example. Accordingly, an area in which the first support unit 22 supports the object 90, which is to be processed, and an area in which the second support unit 23 presses the object 90, which is to be processed, may overlap each other.

In an embodiment, each of the first support unit 22 and the second support unit 23 may include a plurality of support pieces, and the plurality of support pieces may be arranged along the outline of the object 90, which is to be processed. In an embodiment, it may also be understood that the support pieces of the first support unit 22 and the second support unit 23 are arranged along the outline of the cool plate 24. The second support unit 23 may include a plurality of support pieces, and the contact member 231 (refer to FIG. 2A) and the magnetic member 232 may be provided in a plurality of numbers on each of the support pieces.

The plurality of embossings 241 of the cool plate 24 may be arranged along an edge area of the cool plate 24. The plurality of embossings 241 may not overlap the first support unit 22 or the second support unit 23. The plurality of embossings 241 may be arranged along the edge area of the cool plate 24 and may substantially form a frame shape. In an embodiment, the frame shape formed by the plurality of embossings 241 may overlap the edge area of the object 90, which is to be processed. In this case, it may be understood that the edge area of the object 90, which is to be processed, pressed by the plurality of embossings 241 is closer to a central portion of the object 90, which is to be processed, than the edge area of the object 90, which is to be processed, clamped by the first support unit 22 and the second support unit 23. In an embodiment, the cool plate 24 may include an alignment mark 244 disposed in a corner portion. In an embodiment, the alignment mark 244 may be used to align the cool plate 24 and the object 90, which is to be processed.

The cool plate 24 may define a first groove 242 overlapping the second support unit 23. In an embodiment, the first groove 242 of the cool plate 24 may be defined in an edge area of the cool plate 24 and may be opened towards a periphery of the cool plate 24. In an embodiment, in a plan view (e.g., when viewed from the second direction DR2), the first groove 242 of the cool plate 24 may be larger than the second support unit 23. Therefore, the second support unit 23 may be accommodated within the first groove 242 of the cool plate 24. When the second support unit 23 moves in the second direction DR2, the second support unit 23 may pass through the first groove 242 of the cool plate 24 so that the cool plate 24 may not interfere with the movement of the second support unit 23. In an embodiment, the cool plate 24 may include a plurality of first grooves 242. In an embodiment, the cool plate 24 may define a number of first grooves 242 corresponding to the number of second support units 23. In an embodiment, the cool plate 24 may define a number of first grooves 242 equal to the number of support pieces of the second support unit 23, for example.

FIG. 8 is an enlarged plan view illustrating an embodiment of a portion of a device for manufacturing a display panel.

FIG. 8 shows the first support unit 22, the second support unit 23, and the magnetic force unit 25. The cool plate 24 (refer to FIG. 1) is omitted for convenience of illustration.

Referring to FIGS. 1, 7, and 8 together, it may be understood that the support pieces of the first support unit 22 and the second support unit 23 are arranged along the outline of the object 90, which is to be processed, the outline of the cool plate 24, and the outline of the magnetic force unit 25.

The magnetic force unit 25 may include a plurality of magnets 251. In an embodiment, the magnetic force unit 25 may include a plurality of third magnets 2511 and a plurality of fourth magnets 2512. In an embodiment, the plurality of third magnets 2511 and the plurality of fourth magnets 2512 may extend in a single direction, e.g., in the second direction DR2. In an embodiment, the plurality of third magnets 2511 and the plurality of fourth magnets 2512 may be alternately arranged in a direction (e.g., in the first direction DR1) crossing the direction in which each of the plurality of third magnets 2511 and the plurality of fourth magnets 2512 each extend (e.g., the second direction DR2). In an embodiment, the plurality of third magnets 2511 and the plurality of fourth magnets 2512 may be arranged such that directions of the poles of each magnet are opposite to each other. In an embodiment, the N poles of the plurality of third magnets 2511 may be directed toward the second direction DR2, and the N poles of the plurality of fourth magnets 2512 may be directed toward the opposite direction of the second direction DR2, for example. In other words, the N poles of the plurality of third magnets 2511 may be directed toward the opposite direction of the second direction DR2, and the N poles of the plurality of fourth magnets 2512 may be directed toward the second direction DR2.

In an embodiment, the plurality of first magnets 2321, the plurality of second magnets 2322, the plurality of third magnets 2511, and the plurality of fourth magnets 2512 may extend in the same direction (e.g., in the second direction DR2). In an embodiment, the plurality of first magnets 2321, the plurality of second magnets 2322, the plurality of third magnets 2511, and the plurality of fourth magnets 2512 may be arranged in the same direction (e.g., in the first direction DR1). In an embodiment, the plurality of first magnets 2321 and the plurality of second magnets 2322 may be alternately arranged with each other, and the plurality of third magnets 2511 and the plurality of fourth magnets 2512 may be alternately arranged with each other. However, this is an illustrative embodiment, and the directions in which the plurality of first magnets 2321, the plurality of second magnets 2322, the plurality of third magnets 2511, and the plurality of fourth magnets 2512 extend and are arranged may be variously modified.

The magnetic force unit 25 may define a second groove 252 overlapping the second support unit 23. In an embodiment, the second groove 252 of the magnetic force unit 25 may be defined in an edge area of the magnetic force unit 25 and may be opened towards a periphery of the magnetic force unit 25. In an embodiment, in a plan view (e.g., when viewed from the second direction DR2), the second groove 252 of the magnetic force unit 25 may be larger than the second support unit 23. Therefore, the second support unit 23 may be accommodated within the second groove 252 of the magnetic force unit 25. When the second support unit 23 moves in the second direction DR2, the second support unit 23 may pass through the second groove 252 of the magnetic force unit 25, and thus, the magnetic force unit 25 may not interfere with the movement of the second support unit 23. In an embodiment, the magnetic force unit 25 may include a plurality of second grooves 252. In an embodiment, the magnetic force unit 25 may define a number of second grooves 252 corresponding to the number of second support units 23. In an embodiment, the magnetic force unit 25 may define a number of second grooves 252 equal to the number of support pieces of the second support unit 23. In an embodiment, the first groove 242 of the cool plate 24 and the second groove 252 of the magnetic force unit 25 may overlap each other, for example.

The third magnet 2511 or the fourth magnet 2512 of the magnetic force unit 25 may not be disposed in the area where the second groove 252 exists. In an area where the deposition mask 27 overlaps the second groove 252, the magnetic force unit 25 may not be capable of applying magnetic force to the deposition mask 27. The absence of magnetism for the deposition mask 27 which may occur in the second groove 252 may be resolved by the magnetic member 232 of the second support unit 23. In an embodiment, the second support unit 23 may be disposed to overlap the second groove 252 of the magnetic force unit 25, and may include the magnetic member 232 having the plurality of first magnets 2321 and the plurality of second magnets 2322 to apply magnetic force to the deposition mask 27, for example.

In an embodiment, the second support unit 23 of a predetermined size may be desired to clamp a small-sized object 90, which is to be processed, and the second groove 252 of a predetermined size may be desired to avoid collision between the magnetic force unit 25 and the second support unit 23. When the size of the second groove 252 increases, the area in which the magnets 251 of the magnetic force unit 25 may be disposed may decrease. Even when the size of the second support unit 23 increases and the size of the second groove 252 increases, and accordingly the amount (or area) of magnets 251 of the magnetic force unit 25 decreases, because the second support unit 23 includes the magnetic member 232, the magnetic force applied to the deposition mask 27 may be maintained constant.

FIGS. 9A to 9G are cross-sectional views schematically illustrating an embodiment of processes of a method of manufacturing a display panel.

Referring to FIG. 9A, the object 90, which is to be processed, may be loaded into the chamber 21 from the outside of the chamber 21 through the opening area 21-1 provided in the chamber 21. Although not shown, a suitable transport means (e.g., a shuttle or a robotic arm) may be used to load the object 90, which is to be processed, into the chamber 21.

Referring to FIG. 9B, after the object 90, which is to be processed, is loaded into chamber 21, the gate valve 211 may be locked. The object 90, which is to be processed, loaded into the chamber 21 may be disposed (e.g., mounted) on the first support unit 22. In an alternative embodiment, the object 90, which is to be processed, may be supported by the first support unit 22. The first support unit 22 may support the edge area of the object 90, which is to be processed. In this case, a support member of a suitable size corresponding to the size of the object 90, which is to be processed, may be selected and used through the above-described structure of the first support unit 22.

Referring to FIG. 9C, the second support unit 23 may be brought close to the object 90, which is to be processed. In an embodiment, the second support unit 23 may be lowered (e.g., moved in the opposite direction of the third direction DR3) to contact the object 90, which is to be processed. In an alternative embodiment, the second support unit 23 may be lowered to press the object 90, which is to be processed. The second support unit 23 may press the edge area of the object 90, which is to be processed. Accordingly, the object 90, which is to be processed, may be clamped between the first support unit 22 and the second support unit 23. The edge area of the object 90, which is to be processed, may be clamped between the first support unit 22 and the second support unit 23.

Referring to FIG. 9D, the first support unit 22, the second support unit 23, and the object 90, which is to be processed, clamped between the first support unit 22 and the second support unit 23 may be moved integrally toward the deposition mask 27. In an embodiment, the first support unit 22, the second support unit 23, and the object 90, which is to be processed, may be integrally lowered (e.g., moved in the opposite direction of the third direction DR3) and brought into contact with the deposition mask 27. In another embodiment, the deposition mask 27 may be raised (e.g., moved in the third direction DR3) to contact the object 90, which is to be processed.

Referring to FIG. 9E, the cool plate 24 and the magnetic force unit 25 may be moved toward the object 90, which is to be processed. In an embodiment, the cool plate 24 and the magnetic force unit 25 may be lowered (e.g., moved in the opposite direction of the third direction DR3) to be brought closer to the object 90, which is to be processed. In an embodiment, the cool plate 24 and the magnetic force unit 25 may move integrally as a single unit. In an embodiment, the cool plate 24 and the magnetic force unit 25 may move individually. When the cool plate 24 and the magnetic force unit 25 are moved, the second support unit 23 may not interfere with the movement of the cool plate 24 and the magnetic force unit 25 due to the presence of the first and second grooves 242 and 252 (refer to FIGS. 7 and 8) respectively provided in the cool plate 24 and the magnetic force unit 25. In an embodiment, an area in which the first support unit 22 supports the object 90, which is to be processed, an area in which the second support unit 23 presses the object 90, which is to be processed, and the first and second grooves 242 and 252 of the cool plate 24 and the magnetic force unit 25 (refer to FIGS. 7 and 8) may overlap one another.

In an embodiment, the cool plate 24 may be brought into contact with the object 90, which is to be processed, and may press the object 90, which is to be processed. In an embodiment, magnetic force may be applied to the deposition mask 27 through a magnet provided in the magnetic force unit 25 so as to pull the deposition mask 27 toward the magnetic force unit 25 and the object 90, which is to be processed, (e.g., in the third direction DR3). Because the magnetic member 232 of the second support unit 23 (refer to FIG. 8) may be disposed in an area where a magnet of the magnetic force unit 25 is not disposed, an area corresponding to the second groove 252 of the magnetic force unit 25 (refer to FIG. 8), magnetic force pulling in the third direction DR3 may be applied to the deposition mask 27 also in that area, for example. Through the above, the object 90, which is to be processed, and the deposition mask 27 may be (e.g., completely) adhered to each other.

Referring to FIG. 9F, the first support unit 22 and the second support unit 23 may be removed. Because the cool plate 24 presses the object 90, which is to be processed, and the magnetic force unit 25 pulls the deposition mask 27 toward the object 90, which is to be processed, the object 90, which is to be processed, may be fixed at a desired position. Accordingly, clamping of the first support unit 22 and the second support unit 23 may no longer be desired, and thus, the first support unit 22 and the second support unit 23 may be avoided prior to the deposition process shown in FIG. 9G. In an embodiment, the first support unit 22 may be removed by being moved in the first direction DR1 or in the opposite direction, for example. In an embodiment, the second support unit 23 may be moved in the third direction DR3 and removed. Because the cool plate 24 and the magnetic force unit 25 have the first and second grooves 242 and 252 (refer to FIGS. 7 and 8), respectively, the movement of the second support unit 23 in the third direction DR3 may not be disrupted.

Referring to FIG. 9G, a deposition process may be performed by operating the deposition source 26 to arrange a deposition material 261 on the object 90, which is to be processed. In an embodiment, the deposition source 26 may have a nozzle for spraying the deposition material 261 toward the deposition mask 27 and the object 90, which is to be processed. In an embodiment, the deposition material 261 may be disposed on the object 90, which is to be processed, through holes 273 in the mask sheet 272 of the deposition mask 27. In an embodiment, the deposition material 261 may be disposed on one side of the object 90, which is to be processed, on a side facing opposite to the third direction DR3, for example. The deposition material 261 which has passed through the holes 273 in the mask sheet 272 may be disposed on the object 90, which is to be processed, with the same shape or pattern as the holes 273. The shape or pattern of the deposition material 261 may be implemented through a design of the holes 273 in the mask sheet 272. In an embodiment, before the deposition process is performed, pressure inside the chamber 21 may be made equal to or similar to a vacuum by the pressure control unit 29. In an embodiment, the object 90, which is to be processed, in which the deposition process is completed may be discharged out of the chamber 21.

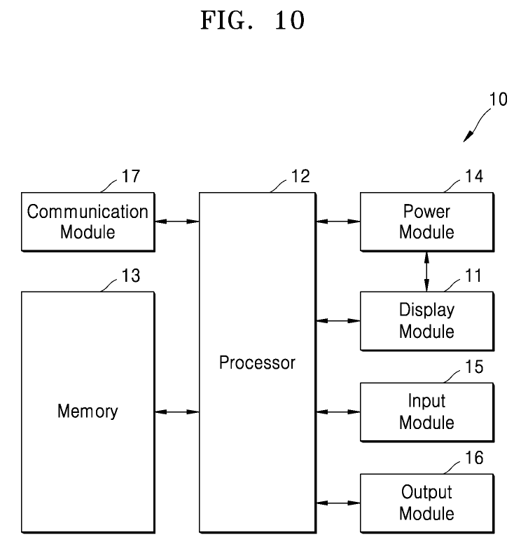

FIG. 10 is a block diagram of an embodiment of an electronic device.

Referring to FIG. 10, an electronic device 10 may include a display panel 11, a processor 12, a memory 13, and a power module 14. In an embodiment, the display panel 11 may be manufactured by the device 20 for manufacturing a display panel or the method for manufacturing a display panel, described above with reference to FIGS. 1 to 9G.

The processor 12 may include at least one of a central processing unit (“CPU”), an application processor (“AP”), a graphics processing unit (“GPU”), a communication processor (“CP”), an image signal processor (“ISP”), and a controller. In an embodiment, the processor 12 may be provided split into two or more units from a functional or structural perspective. In an embodiment, the processor 12 may include a main processor in the form of a first driving chip including a CPU, and an auxiliary processor in the form of a second driving chip including a controller which receives an image signal from the main processor and processes the image signal to meet the interface specifications of the display panel 11, for example.

The memory 13 may include at least one of non-volatile memory and volatile memory. The memory 13 may store data information desired for an operation of the processor 12 or display panel 11. When the processor 12 executes an application stored in the memory 13, image data signals and/or input control signals may be transmitted to the display panel 11, and the display panel 11 may process the received signals and output image information through a display screen.

The power module 14 may include a power supply module, such as a power adapter or a battery device, and a power conversion module which converts power supplied by the power supply module to generate power desired for an operation of the electronic device 10. Power conversion by the power conversion module may include, but is not limited to, direct current (“DC”)-DC conversion, alternating current (“AC”)-DC conversion, and DC-AC conversion.

The electronic device 10 may further include an input module 15, a non-image output module 16, and/or a communication module 17.

The input module 15 may provide input information to the processor 12 and/or the display panel 11. The input module 15 may include various sensor modules as well as physical buttons, keyboard, and microphone. In embodiments, the sensor modules may include biosensors, such as blood pressure sensors, blood sugar sensors, electrocardiogram sensors, and heart rate sensors, as well as touch sensors, pressure sensors, distance sensors, position sensors, digitizers, motion recognition sensors, camera sensors, photodetectors, photoelectric conversion sensors, temperature sensors.

The non-image output module 16 may receive information other than the image transmitted from the processor 12 and provide the received information to the user. In embodiments, the non-image output module 16 may include sound modules, haptic modules, light-emitting modules, or the like, and may include other functional modules unique to the electronic device (e.g., a cooling module in a refrigerator).

The communication module 17 is a module responsible for transmitting and receiving information between the electronic device 10 and an external device, and may include a reception unit and a transmission unit. The communication module 17 may include various wireless communication modules, such as a mobile communication module, a Wireless Fidelity (“Wi-Fi”) module, or a Bluetooth module, or various wired communication modules.

At least one of the components of the electronic device 10 described above may be included in the display device. In addition, some of individual modules functionally included within a single module may be included within the display device, and other individual modules may be provided separately from the display device. In an embodiment, the display device may include the display panel 11, and the processor 12, the memory 13, and the power module 14 may be provided in the form of other devices within the electronic device 10 which is not the display device, for example. In another embodiment, the power module 14 may be provided within the display device and supply power to the processor 12 and memory 13 provided within the electronic device 10, which is not the display device. However, one or more the disclosure is not limited to the examples described above.

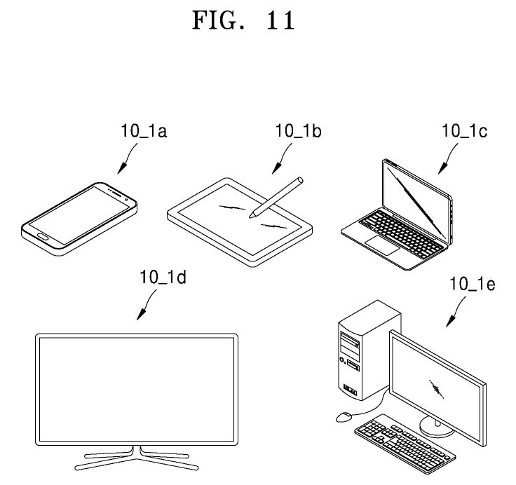

FIGS. 11 to 13 are schematic diagrams of embodiments of electronic devices. FIGS. 11 to 13 show embodiments of various electronic devices to which display devices are applied.

FIG. 11 shows embodiments of electronic devices, such as a smartphone 10_1a, a tablet personal computer (“PC”) 10_1b, a laptop 10_1c, a television (“TV”) 10_1d, and a desk monitor 10_1e.

The smartphone 10_1a may include an input module, such as a touch sensor, and a communication module in addition to the display panel. The smartphone 10_1a may process information received through the communication module or other input modules and display the information through a display panel of the display device.

The tablet PC 10_1b, the laptop 10_1c, the TV 10_1d, and the desk monitor 10_1e may also include a display panel and an input module, similar to smartphone 10_1a, and may further include a communication module in some cases.

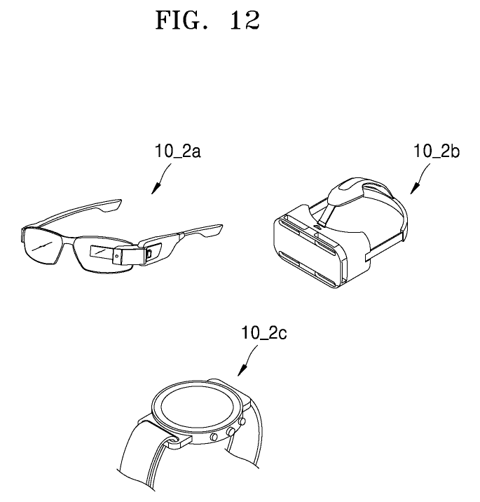

FIG. 12 shows an embodiment in which an electronic device including a display panel is applied to a wearable electronic device. The wearable electronic device may be smart glasses 10_2a, a head-mounted display 10_2b, a smart watch 10_2c, or the like.

The smart glasses 10_2a and the head-mounted display 10_2b may include a display panel which emits a display image and a reflector which reflects the emitted display image and provides the reflected display image to the user's eyes, thereby providing a virtual-reality or augmented-reality screen to the user.

The smart watch 10_2c includes a biometric sensor as an input device and may provide biometric information recognized by the biometric sensor to the user through a display panel.

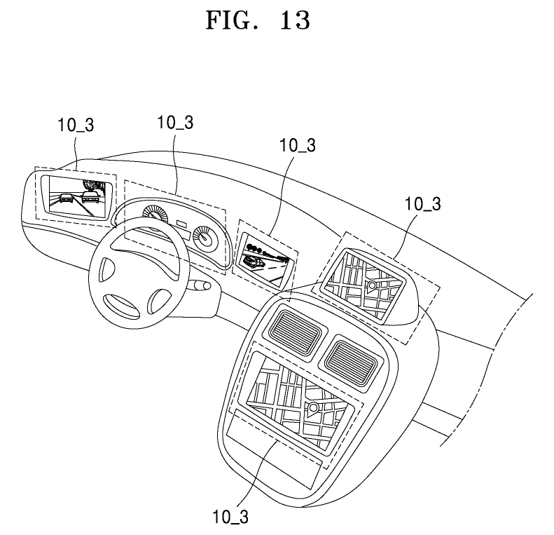

FIG. 13 shows an embodiment in which an electronic device including a display panel is applied to a vehicle. In an embodiment, an electronic device 10_3 may be applied to a dashboard, center fascia, or the like of a vehicle, or may be applied to a center information display (“CID”) disposed on a dashboard of a vehicle or a room mirror display replacing a side mirror, for example.

Although not shown, an electronic device to which the display device according to the embodiments are applied may include not only devices which mainly display screens, such as billboards, electronic boards, and game consoles, but also various home appliances which display information through display panels, such as refrigerators, washing machines, dryers, air conditioners, and robot vacuum cleaners. In addition, when the display panel has a function of transmitting light, the display panel may be applied to electronic devices, such as smart windows or transparent display devices which display a background and a displayed image together. Types of electronic device according to the one or more the disclosure is not limited to those described above as examples, and application to various other electronic devices not described above as examples may also be possible.

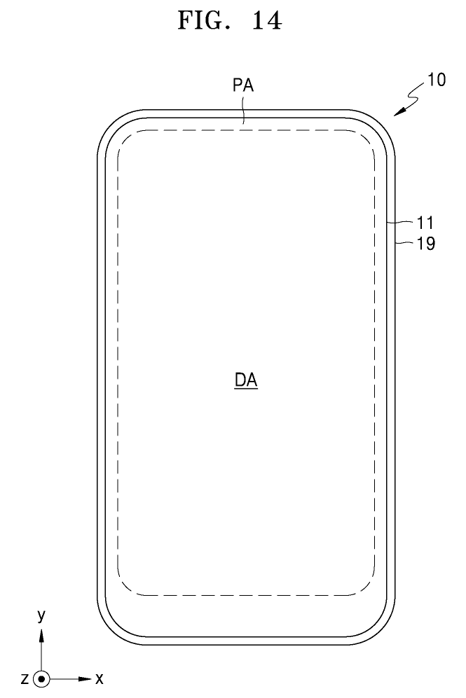

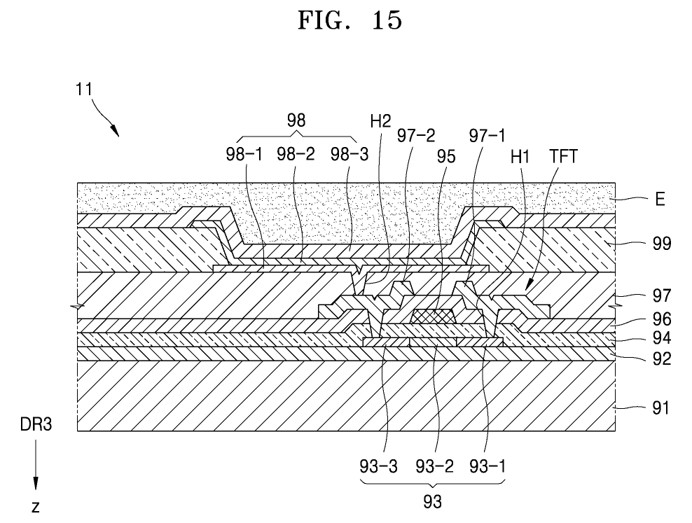

FIG. 14 is a schematic plan view of an embodiment of the electronic device 10. FIG. 15 is a cross-sectional view of an embodiment of the display panel 11.

FIG. 14 shows an embodiment in which the electronic device 10 is a smartphone, but the disclosure is not necessarily limited thereto. The electronic device 10 may include the display panel 11 and a housing 19. In an embodiment, the display panel 11 may be accommodated within the housing 19. In other words, a method of manufacturing an electronic device may include coupling the display panel 11 with the housing 19, or accommodating the display panel 11 within the housing 19. The housing 19 is not necessarily implemented in the form shown in FIG. 14, and any housing that provides a space in which the display panel 11 may be accommodated may belong to the housing 19 referred to herein without being limited in type or form.

Referring to FIGS. 14 and 15, a display area DA and a peripheral area PA outside the display area DA may be defined on a substrate 91 of the display panel 11. A light-emitting element 98 may be disposed in the display area DA, and power wiring (not shown) may be disposed in the peripheral area PA.

A plurality of deposition material patterns may be arranged in the display area DA. In FIG. 14, the display panel 11 and the display area DA are shown as being approximately square, but the disclosure is not necessarily limited thereto. The display panel 11 and/or the display area DA may have other shapes, e.g., an amorphous shape.

The display panel 11 may include the substrate 91, a thin-film transistor TFT disposed on the substrate 91, and the light-emitting element 98 disposed on the thin-film transistor TFT. The light-emitting element 98 may be electrically connected to the thin-film transistor TFT.

The substrate 91 may include a plastic material, or may include a metal material. In an embodiment, the substrate 91 may include polyimide (“PI”). The thin-film transistor TFT may be disposed on the substrate 91, a via layer 97 may be disposed to cover the thin-film transistor TFT, and the light-emitting element 98 may be disposed on the via layer 97.

A buffer layer 92 including an inorganic insulating material may be further disposed on an upper surface of the substrate 91. The buffer layer 92 may include silicon oxide (SiO₂), silicon nitride (SiNₓ), and/or silicon oxynitride (SiON).

An active layer 93 may be disposed in a predetermined pattern on the buffer layer 92, and the active layer 93 may be covered by a gate insulating layer 94. The active layer 93 may have a source region 93-1 and a drain region 93-3, and may have a channel region 93-2 between the source region 93-1 and the drain region 93-3.

The active layer 93 may be formed to include various materials. In an embodiment, the active layer 93 may include an inorganic semiconductor material, such as amorphous silicon or crystalline silicon. In an embodiment, the active layer 93 may include or consist of an oxide semiconductor. In an embodiment, the active layer 93 may include an organic semiconductor material.

The active layer 93 may be formed by forming an amorphous silicon film on the buffer layer 92, crystallizing the amorphous silicon film to form a polycrystalline silicon film, and then patterning the polycrystalline silicon film. The active layer 93 may be doped with impurities in the source region 93-1 and the drain region 93-3.

On an upper surface of the gate insulating layer 94, a gate electrode 95 corresponding to the active layer 93 and an inter-insulating layer 96 covering the gate electrode 95 may be arranged. After defining a contact hole H1 in the inter-insulating layer 96 and the gate insulating layer 94, a source electrode 97-1 and a drain electrode 97-2 may be arranged on the inter-insulating layer 96 such that the source electrode 97-1 and the drain electrode 97-2 contact the source region 93-1 and the drain region 93-3, respectively.

The via layer 97 may be disposed on the thin-film transistor TFT, and a pixel electrode 98-1 of the light-emitting element 98 may be disposed on the via layer 97. The pixel electrode 98-1 may contact the drain electrode 97-2 of the thin-film transistor TFT through a via hole H2 defined in the via layer 97. The via layer 97 may include inorganic and/or organic materials, and a single layer or two or more layers, and may be formed as a planarizing film so that an upper surface of the via layer 97 is flat regardless of the curvature of a film under the via layer 97, or may be formed so as to have a curvature which follows the curvature of the film under the via layer 97.

After arranging the pixel electrode 98-1 on the via layer 97, a pixel-defining film 99 may be formed to cover the pixel electrode 98-1 and the via layer 97, and the pixel-defining film 99 may be opened so that a portion of the pixel electrode 98-1 is exposed.

An intermediate layer 98-2 and an opposite electrode 98-3 may be arranged on the pixel electrode 98-1. The opposite electrode 98-3 may be disposed on the intermediate layer 98-2 and the pixel-defining film 99. In an embodiment, the opposite electrode 98-3 may be disposed on an entirety of the surface of the substrate 91.

The intermediate layer 98-2 may have an emission layer. In another optional example, the intermediate layer 98-2 may have an emission layer, and may further have at least one of a hole injection layer, a hole transport layer, an electron transport layer, and an electron injection layer. The disclosure is not limited thereto, and the intermediate layer 98-2 may have the emission layer and may further include various other functional layers (not shown).

The pixel electrode 98-1 and the opposite electrode 98-3 may be insulated from each other by the intermediate layer 98-2. Voltages of different polarities may be applied to the intermediate layer 98-2 by the pixel electrode 98-1 and the opposite electrode 98-3, so that light may be emitted from the emission layer included in the intermediate layer 98-2.

The intermediate layer 98-2 may be provided in a plurality of numbers, and the plurality of intermediate layers 98-2 may form the display area DA. In this case, the plurality of intermediate layers 98-2 may be arranged and spaced apart from each other within the display area DA. In an embodiment, the intermediate layer 98-2 may be disposed in a predetermined pattern within the display area DA, and the device 20 for manufacturing a display panel (refer to FIG. 1) described above may be used to arrange the intermediate layer 98-2 in this pattern.

A thin-film encapsulation layer E may include a plurality of inorganic layers, or an inorganic layer and an organic layer. The organic layer of the thin-film encapsulation layer E may include a polymer, and may be a single film or laminated film including any one of polyethylene terephthalate, PI, polycarbonate, epoxy, polyethylene, and polyacrylate, for example. The inorganic layer of the thin-film encapsulation layer E may be a single film or laminated film including a metal oxide or a metal nitride. In an embodiment, the inorganic layer may include any one of SiO₂, SiNₓ, SiON, aluminum oxide (Al₂O₃), and titanium oxide (TiO₂), for example. An uppermost layer in the thin-film encapsulation layer E which is exposed to the outside may be formed as an inorganic layer to prevent moisture penetration to the light-emitting element.

The thin-film encapsulation layer E may include at least one sandwich structure in which at least one organic layer is inserted between at least two inorganic layers. In another embodiment, the thin-film encapsulation layer E may include at least one sandwich structure in which at least one inorganic layer is inserted between at least two organic layers. In another embodiment, the thin-film encapsulation layer E may include a sandwich structure in which at least one organic layer is inserted between at least two inorganic layers and a sandwich structure in which at least one inorganic layer is inserted between at least two organic layers.

According to the embodiments described above, a device for manufacturing a display panel having a support unit capable of handling objects of various sizes to be processed may be provided. In addition, a method of manufacturing a display panel capable of handling objects of various sizes to be processed may be provided. In addition, a method of manufacturing an electronic device, including a method of manufacturing the display panel may be provided.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A device for manufacturing a display panel from an object, the device comprising:
a chamber;
a first support unit which is disposed within the chamber and supports an edge area of the object to be processed; and
a second support unit which is disposed on the first support unit and presses the edge area of the object to be processed, the second support unit including:
a contact member facing the first support unit; and
a magnetic member including a magnet.

2. The device of claim 1, wherein the magnetic member is disposed on the contact member or embedded in the contact member.

3. The device of claim 1, wherein the first support unit comprises a first support member which is in direct contact with the object to be processed and supports the object to be processed, and a hinge member connected to the first support member.

4. The device of claim 3, wherein the first support unit further comprises a second support member which is rotatably connected to the hinge member and has a size different from a size of the first support member.

5. The device of claim 1, further comprising:
a cool plate disposed on the second support unit; and
a magnetic force unit disposed on the cool plate.

6. The device of claim 5, wherein the cool plate includes an embossing which protrudes in a direction toward the object to be processed.

7. The device of claim 5, wherein grooves are respectively defined in the cool plate and the magnetic force unit in the edge area, and
the grooves overlap the second support unit.

8. The device of claim 1, wherein an area in which the first support unit supports the object to be processed and an area in which the second support unit presses the object to be processed overlap each other.

9. The device of claim 1, wherein the second support unit includes a plurality of contact members and a plurality of magnetic members, and the plurality of contact members and the plurality of magnetic members are arranged along an outline of the object to be processed.

10. The device of claim 1, further comprising:
a deposition source disposed within the chamber and facing the object to be processed; and
a deposition mask disposed between the object to be processed and the deposition source.

11. A method of manufacturing a display panel, the method comprising:
loading an object to be processed into a chamber;
supporting an edge area of the object to be processed by a first support unit;
pressing the edge area of the object to be processed by a second support unit; and
arranging a deposition material on the object to be processed,
wherein the second support unit includes a contact member facing the first support unit and in contact with the object to be processed and a magnetic member including a magnet.

12. The method of claim 11, wherein the first support unit comprises a first support member which is in direct contact with the object to be processed and supports the object to be processed, and a hinge member connected to the first support member.

13. The method of claim 12, wherein the first support unit further comprises a second support member which is rotatably connected to the hinge member and has a size different from a size of the first support member.

14. The method of claim 11, further comprising bringing the object to be processed into contact with a deposition mask provided within the chamber.

15. The method of claim 14, further comprising:
bringing a cool plate into contact with the object to be processed; and
bringing the object to be processed and the deposition mask into close contact with each other through a magnetic force unit.

16. The method of claim 15, wherein grooves are respectively defined in the cool plate and the magnetic force unit in the edge area, and
the grooves overlap the second support unit.

17. The method of claim 16, wherein an area in which the first support unit supports the object to be processed, an area in which the second support unit presses the object to be processed, and the grooves in the cool plate and the magnetic force unit overlap one another.

18. A method of manufacturing an electronic device, the method comprising:
preparing a display panel; and
coupling the display panel with a housing,
wherein the preparing of the display panel comprises:
loading an object to be processed into a chamber;
supporting an edge area of the object to be processed by a first support unit;
pressing the edge area of the object to be processed by a second support unit; and
arranging a deposition material on the object to be processed,
wherein the second support unit includes a contact member facing the first support unit and in contact with the object to be processed, and a magnetic member including a magnet.

19. The method of claim 18, wherein the first support unit comprises a first support member which is in direct contact with the object to be processed and supports the object to be processed, and a hinge member connected to the first support member.

20. The method of claim 19, wherein the first support unit further comprises a second support member which is rotatably connected to the hinge member and has a size different from a size of the first support member.
